(19) United States
(12) Patent Application Publication
(10) Pub. No.: US 2011/0100684 A1
(43) Pub. Date: May 5, 2011

(54) METHOD FOR MANUFACTURING AN ELECTRICAL CONDUCTOR BY APPLYING AT LEAST ONE PASTE, IN PARTICULAR A THICK-FILM PASTE

(76) Inventors: Peter Hornig, Pliezhausen (DE); Mark Leverkoehne, Homburg-Beeden (DE); Philipp Janovsky, Reutlingen (DE); Bernd Maihoefer, Salach (DE); Juergen Egerter, Reutlingen (DE); Walter Roethlingshofer, Reutlingen (DE); Stefan Keil, Tuebingen (DE); Harald Neumann, Oberriexingen (DE); Heike Schluckwerder, Salmendingen (DE); Markus Werner, El Paso, TX (US); Ulrich Speh, Steinenbronn (DE); Frank Westphal, Vaihingen/Enz (DE); Josef Weber, Oberriexingen (DE)

(21) Appl. No.: 12/810,738

(22) PCT Filed: Dec. 19, 2008
(86) PCT No.: PCT/EP08/68074

§ 371 Date: Jan. 21, 2011

(30) Foreign Application Priority Data
Dec. 27, 2007 (DE) 102007063282.9

(51) Int. Cl. H05K 1/02; H05K 3/10; H01C 17/065; B05D 3/06

(52) U.S. Cl. 174/256; 427/58; 427/102; 427/555

(57) ABSTRACT

A method for manufacturing an electrical conductor by applying at least one paste, in particular a thick-film paste, to a substrate by a dispensing operation, wherein the paste is applied in at least one strand.

### FIELD OF THE INVENTION

The present invention relates to a method for manufacturing an electrical conductor on a substrate.

### BACKGROUND INFORMATION

Resistors and, prior to that, the resistor connection are implemented by screen printing on today's thick-film substrates (LTCC, low-temperature cofired ceramics, standard hybrids). The different resistance values are adjusted using pastes of different resistance decades and through the geometry of the resistor as well as by subsequent trimming cuts using a laser beam.

The technology today has the following restrictions: in the case of up to six different resistance layers, drying steps are necessary between the individual printings. After the second printing, topography effects result in deviations in layer thickness and thus increased scattering ranges in the resistance values. Great allowances with regard to the target value before the final laser trim are required due to this wide scattering range, resulting in long laser times.

In addition, German patent document DE 10 2004 044 144 A1 discusses dropwise application of colloid inks, forming resistance films on a substrate.

### SUMMARY OF THE INVENTION

An aspect of the exemplary embodiments and/or exemplary methods of the present invention is the use of a dispensing operation for applying metal plating pastes and/or resistors in strands to the unfired tape or to the fired ceramic. Thus, accurate dosing while avoiding topography effects is possible by dispensing resistor pastes, for example. Each decade is applied via a separate metering head. With the help of sample analyses, it is easily possible to regulate the resistor geometry, so that allowances with regard to the target value before the final laser trim may turn out to be a great deal smaller or the target value may be adjusted directly, so that the laser trim is definitely shortened or may even be omitted.

Diluted or undiluted thick-film pastes may be dispensed in strands or by drops (inkjet principle). The print may be applied mechanically, electromagnetically, or by piezoelectric elements. Drops (slightly diluted resistor pastes) may be applied by pushbutton using a piezoelectric bending transducer and a ceramic or ceramic-coated plunger-nozzle pairing.

The exemplary embodiments and/or exemplary methods of the present invention is explained in greater detail below as an example with reference to the figures.

### BRIEF DESCRIPTION OF THE DRAWINGS

FIG. 1 shows the design of the electrical conductor with the aid of single strands.

FIG. 2 shows the design of the electrical conductor with the aid of a continuous single strand.

### DETAILED DESCRIPTION

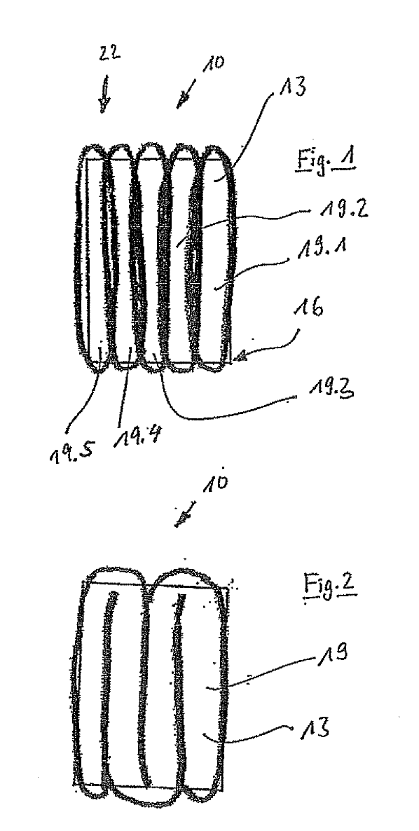

FIG. 1 schematically shows the configuration of an electrical conductor 10. This conductor 10 is produced by applying strands of paste 13, for example, resistor paste, to a substrate 16. Various strands 19.1 through 19.5 are applied to substrate 16 side by side according to length, and contact one another on their mutually facing longitudinal sides 22.

This conductor 10 is manufactured by a method for manufacturing an electrical conductor 10 by applying at least one paste 13, in particular a thick-film paste, to a substrate 16 by a dispensing operation. Paste 13 is applied in at least one strand 19, in this example in five strands 19.1 through 19.5.

Paste 13 may be applied in parallel strands 19.1 through 19.5.

If conductor 10 is a resistor, then each resistance decade, for example, a strand 19.3, may be applied by a separate metering head.

FIG. 2 also shows schematically the design of an electrical conductor 10. This conductor 10 is applied to a substrate 16 by a continuous, here serpentine-type strand 19 of paste 13, for example, resistor paste. The various mutually parallel sections of strand 19 also contact one another on their mutually facing longitudinal sides 22.

Paste 13 may be a metal plating paste or a resistor paste, depending on the choice.

After application of paste 13, a firing operation is performed and subsequently a laser trim, if necessary.

In a step prior to the actual fabrication (pilot production, for example), the dispensing method may be performed at least once in a trial run, then substrate 16 fired with paste(s) 13 and a target value, in particular a resistance value, may be ascertained.

Depending on the deviation from the target value, a laser trim is then ascertained.

For application of paste 13, a device which operates mechanically or electromagnetically or a piezoelectric element may be used.

Substrate 16 is an unfired tape or a fired ceramic.

1-10. (canceled)

11. A method for manufacturing an electrical conductor, the method comprising:
providing a substrate; and
applying at least one paste to the substrate by a dispensing operation, wherein the paste is applied in at least one strand.

12. The method of claim 11, wherein the paste is applied one of (i) in strands positioned side by side, and (ii) in a continuous strand.

13. The method of claim 11, wherein the electrical conductor is a resistor, and each resistance decade is applied by a separate metering head.

14. The method of claim 11, wherein the paste is one of a metal plating paste and a resistor paste.

15. The method of claim 11, further comprising:
performing, after applying the paste, a firing operation; and
performing a laser trim if necessary.

16. The method of claim 11, wherein in a preceding operation, the applying is performed at least once in a trial run, followed by a firing, and wherein a target value, which is a resistance value, is determined.

17. The method of claim 16, wherein it is determined that a laser trim is needed depending on a deviation from a target value.

18. The method of claim 11, wherein one of a mechanically operating device, an electromagnetic operating device, and a piezoelectric element is used to apply the paste.

19. The method of claim 11, wherein the substrate is one of an unfired tape and a fired ceramic.

20. A substrate, comprising:
a substrate arrangement; and
an electrical conductor, wherein the electrical conductor is made by applying at least one paste to the substrate arrangement by a dispensing operation, and wherein the paste is applied in at least one strand.

21. The method of claim 11, wherein the paste is applied in strands positioned side by side and are parallel to one another.

22. The method of claim 11, wherein the paste is applied in a continuous serpentine-type strand.

23. The method of claim 11, wherein the at least one paste is a thick-film paste.
